(19) United States
(12) Patent Application Publication
(10) Pub. No.: US 2011/0180313 A1
(43) Pub. Date: Jul. 28, 2011

(54) METHOD OF FORMING CIRCUIT INTERCONNECTION, CIRCUIT BOARD, AND CIRCUIT INTERCONNECTION FILM HAVING FILM THICKNESS LARGER THAN WIDTH THEREOF

(75) Inventor: Tomoyuki KAMAKURA, Matsumoto (JP)

(73) Assignee: SEIKO EPSON CORPORATION, Tokyo (JP)

(21) Appl. No.: 13/012,013

(22) Filed: Jan. 24, 2011

(30) Foreign Application Priority Data
Jan. 26, 2010 (JP) 2010-013924

(51) Int. Cl. H05K 1/11; H01B 5/00; C25D 5/02; C25D 7/00

(52) U.S. Cl. 174/262; 174/126.1; 205/126

(57) ABSTRACT

A method of forming a circuit interconnection on a circuit board includes: forming a trench that corresponds to a shape of the circuit interconnection on an interconnection base material that forms the circuit interconnection; performing a liquid repellent process of at least the base material surface of the interconnection base material and a side wall surface of the trench with respect to a liquid body that includes a catalyst for forming a conductive layer; distributing the liquid body that includes the catalyst for forming a conductive layer on the trench; and forming a conductive circuit interconnection film that forms the circuit interconnection by distributing a plating solution in a range that includes the trench and depositing a conductive material from the plating solution through the catalyst for forming the conductive layer.

### BACKGROUND

1. Technical Field

The present invention relates to a method of forming a circuit interconnection on a circuit board, a circuit board formed using the method of forming a circuit interconnection, and a circuit interconnection film which is formed using the corresponding method of forming a circuit interconnection and has a film thickness that is greater than a width thereof.

2. Related Art

For some time, semiconductor devices have been packaged and used on circuit boards. Recently, with the remarkable development of high-performance miniaturized semiconductor devices, miniaturized high-performance circuit boards for mounting these semiconductor devices have also come into demand. In order to achieve miniaturized circuit boards, miniaturized high-density circuit interconnections that form the circuit boards are necessary. In order to make high-performance circuit boards, low resistance circuit interconnections (which have a large cross-sectional area and no defects) are necessary.

JP-A-2005-12181 discloses a method of forming a pattern, a device and a method of manufacturing the device, an electro-optic device, an electronic device, and a method of manufacturing an active matrix substrate. A method of forming a pattern is disclosed, which facilitates the insertion of a functional solution into a circuit interconnection forming area by distributing the functional solution that contains metal as a pattern forming method, forming a portion partially having a wide width on an area where a circuit interconnection is formed as a method of forming the circuit interconnection by solidifying the corresponding functional solution, and inserting the functional solution from the portion having the wide width.

JP-A-2009-117415 discloses a method of forming a circuit which can form a circuit pattern having a thick pattern thickness by forming the circuit pattern, forming an insulating resin layer that covers the corresponding circuit pattern, forming a trench that exposes the circuit pattern on the insulating resin layer, and arranging metal on the trench.

However, according to the method as disclosed in JP-A-2005-12181, if the functional solution containing metal flows into the circuit interconnection forming area, there is a possibility that the functional solution is not sufficiently filled into a portion having a narrow width of the circuit interconnection forming area due to the unevenness of the flow distribution, and thus the film thickness of the circuit interconnection film that forms the circuit interconnection is liable to become non-uniform.

According to the method as disclosed in JP-A-2009-117415, it is impossible to make the width of a circuit interconnection smaller than a predetermined width due to the fact that the width of the circuit interconnection is unable to be smaller than the width of the interconnection of the circuit pattern initially formed. For example, if an ink jet method according to a third aspect of the invention is used, a pattern having a width that is smaller than the landed diameter of the discharged and landed droplets is unable to be formed, and thus the miniaturization thereof is limited.

### SUMMARY

An advantage of some aspects of the invention is to solve at least a portion of the above-described problem, and it is possible to realize the invention in the following forms or application examples.

### APPLICATION EXAMPLE 1

According to this application example of the invention, there is provided a method of forming a circuit interconnection on a circuit board including a trench forming process of forming a trench that corresponds to a shape of the circuit interconnection on an interconnection base material that forms the circuit interconnection; a liquid repellent process of performing a liquid repellent process of at least the base material surface of the interconnection base material and a side wall surface of the trench with respect to a liquid body that includes a catalyst for forming a conductive layer; a catalyst distribution process of distributing the liquid body that includes the catalyst for forming a conductive layer on the trench; and a film forming process of forming a conductive circuit interconnection film that forms the circuit interconnection by distributing a plating solution in a range that includes the trench and depositing a conductive material from the plating solution through the catalyst for forming the conductive layer.

According to the method of forming a circuit interconnection according to this application example, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the nucleation site of the plating, it has no effect on the film thickness of the circuit interconnection film. Also, for example, since the conductive material is deposited by plating such as electroless plating, the possibility of the circuit interconnection film that forms the circuit interconnection becoming non-uniform is substantially eliminated, and thus a uniform circuit interconnection can be formed.

It is possible to select a liquid body having low viscosity and sufficient fluidity as the catalyst for forming the conductive layer, whereby the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a narrow pattern width in a plane direction of the interconnection base material, can be easily formed. Since the width in the plane direction of the interconnection base material is fine, even a circuit interconnection film, of which the thickness in a direction that is substantially orthogonal to the plane direction of the interconnection base material is greater than the width in the plane direction of the interconnection base material, can be easily formed.

By performing the liquid repellent process of the base material surface with respect to the liquid body that includes the catalyst for forming the conductive layer, the distribution of the catalyst for forming the conductive layer on a board surface can be suppressed. By suppressing the distribution of the catalyst for forming the conductive layer on the board surface on which the trench is formed, the conductive layer is formed on the board surface, and thus the short circuit of conductive layers formed in the trench due to the corresponding conductive layer can be suppressed.

By performing the liquid repellent process of the side wall surface of the trench with respect to the liquid body that includes the catalyst for forming the conductive layer, the distribution of the catalyst for forming the conductive layer on the side wall surface of the trench can be suppressed. Accordingly, by depositing a conductive material from the plating solution by the catalyst for forming the conductive layer, the circuit interconnection film is formed through lamination of the conductive material mainly from a bottom surface of the trench when the circuit interconnection film is formed, and thus the circuit interconnection film laminated from one direction and having a uniform cross section can be formed.

### APPLICATION EXAMPLE 2

In the method of forming a circuit interconnection according to the above-described application example, it is preferable that the trench is formed by a laser process in the trench forming process.

According to this method of forming a circuit interconnection, by narrowing the diameter of a laser light, a fine laser process becomes possible, and using a laser process as the method of forming the trench, a trench having a fine line width can be formed, and the trench can be formed precisely. Even a fine trench having a depth larger than the width can be easily formed.

### APPLICATION EXAMPLE 3

The method of forming a circuit interconnection according to the above-described application example may further include a desmear processing process.

According to this method of forming a circuit interconnection, smear can be removed by the desmear processing process. By removing the smear on the inside of the trench and a side wall thereof, it is easy to pour the functional solution that includes the catalyst for forming the conductive layer onto the circuit interconnection film, and thus it is possible to suppress the occurrence of a defect on the circuit interconnection film due to the fact that the functional solution that includes the catalyst for forming the conductive layer is not filled onto the circuit interconnection film.

### APPLICATION EXAMPLE 4

In the method of forming a circuit interconnection according to the above-described application example, it is preferable that the catalyst distribution process includes landing and distributing the liquid body that includes the catalyst for forming the conductive layer on a portion of the trench using an ink jet type discharge device.

According to this method of forming a circuit interconnection, the liquid body that includes the catalyst for forming the conductive layer is distributed on the trench using an ink jet type discharge device. The ink jet type discharge device can distribute an arbitrary amount of the liquid body on an arbitrary position precisely. Accordingly, the liquid body can be distributed on a proper position of the fine trench precisely. Also, an appropriate distribution amount of the liquid body to be distributed can be distributed moderately.

### APPLICATION EXAMPLE 5

In the method of forming a circuit interconnection according to the above-described application example, it is preferable that the catalyst distribution process includes distributing the liquid body that includes the catalyst for forming the conductive layer on a portion having a wide width of the trench, and distributing the distributed liquid body on the portion except for the portion having wide width by capillary force.

According to this method of forming a circuit interconnection, the liquid body can be distributed even in a fine portion by using capillary force. In the case of directly distributing the liquid body to a small trench, the liquid body can be distributed even on the narrow trench, around which the liquid body is distributed due to the small size of the trench, without substantial flowing out of the liquid body from the trench.

### APPLICATION EXAMPLE 6

In the method of forming a circuit interconnection according to the above-described application example, it is preferable that the film forming process includes forming the circuit interconnection film by electroless plating.

According to this method of forming a circuit interconnection, the circuit interconnection film can be selectively formed on the trench portion on which the catalyst for forming the conductive layer is distributed by electroless plating.

### APPLICATION EXAMPLE 7

In the method of forming a circuit interconnection according to the above-described application example, it is preferable that the film forming process includes forming the circuit interconnection film by electroless plating and forming the circuit interconnection film by electro plating.

According to this method of forming a circuit interconnection, the circuit interconnection film can be selectively formed on the trench portion on which the catalyst for forming the conductive layer is distributed by electroless plating. By using both electroless plating and electro plating, the time required for forming the film can be shortened in comparison to a case where the circuit interconnection film is formed only by electroless plating.

### APPLICATION EXAMPLE 8

According to this application example of the invention, there is provided a circuit board including a circuit interconnection that is formed by using a method of forming a circuit interconnection that includes a trench forming process of forming a trench that corresponds to a shape of the circuit interconnection on an interconnection base material that forms the circuit interconnection; a liquid repellent process of performing a liquid repellent process of at least the base material surface of the interconnection base material and a side wall surface of the trench with respect to a liquid body that includes a catalyst for forming a conductive layer; a catalyst distribution process of distributing the liquid body that includes the catalyst for forming a conductive layer on the trench; and a film forming process of forming a conductive circuit interconnection film that forms the circuit interconnection by distributing a plating solution in a range that includes the trench and depositing a conductive material from the plating solution through the catalyst for forming the conductive layer.

According to the circuit board of this application example which has the circuit interconnection formed by the method of forming the circuit interconnection, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the nucleation site of the plating, it has no effect on the film thickness of the circuit interconnection film. Also, since the conductive material is deposited by plating such as electroless plating, the possibility of the circuit interconnection film that forms the circuit interconnection becoming non-uniform is substantially eliminated. Accordingly, a uniform circuit interconnection can be formed.

It is possible to select a liquid body having low viscosity and sufficient fluidity as the catalyst for forming the conductive layer, whereby the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a fine width in a plane direction of the interconnection base material, can be easily formed.

By performing the liquid repellent process of the side wall surface of the trench with respect to the liquid body that includes the catalyst for forming the conductive layer, the distribution of the catalyst for forming the conductive layer on the side wall surface of the trench can be suppressed. Accordingly, by depositing a conductive material from the plating solution by the catalyst for forming the conductive layer, the circuit interconnection film is formed through lamination of the conductive material mainly from a bottom surface of the trench when the circuit interconnection film is formed, and thus the circuit interconnection film laminated from one direction and having a uniform cross section can be formed.

Accordingly, since the fine circuit interconnection which is uniform and has the circuit interconnection film having a fine width in the plane direction of the circuit board can be formed, a circuit board can be realized that can suppress the enlargement thereof resulting from the fact that the circuit interconnection is unable to be fine.

### APPLICATION EXAMPLE 9

In the circuit board according to the above-described application example, it is preferable that the catalyst distribution process includes distributing the liquid body that includes the catalyst for forming the conductive layer on a portion having a wide width of the trench, and distributing the distributed liquid body on the portion except for the portion having wide width due to capillary force.

According to this circuit board, the liquid body can be distributed even in a fine portion by using capillary force when the circuit interconnection having the circuit board is formed. In the case of directly distributing the liquid body to a small trench, the liquid body can be distributed even on the fine trench, around which the liquid body is distributed due to the small size of the trench, without substantially flowing out from the trench.

### APPLICATION EXAMPLE 10

According to this application example of the invention, there is provided a circuit interconnection film, which has a film thickness that is larger than a width of the interconnection film, and is formed using a method of forming a circuit interconnection film that includes a trench forming process of forming a trench that corresponds to a shape of the circuit interconnection film on an interconnection base material that forms the circuit interconnection film; a liquid repellent process of performing a liquid repellent process of at least the base material surface of the interconnection base material and a side wall surface of the trench with respect to a liquid body that includes a catalyst for forming a conductive layer; a catalyst distribution process of distributing the liquid body that includes the catalyst for forming a conductive layer on the trench; and a film forming process of forming a conductive circuit interconnection film by distributing a plating solution in a range that includes the trench and depositing a conductive material from the plating solution through the catalyst for forming the conductive layer.

According to the circuit interconnection film which has a film thickness that is larger than a width of the interconnection film of this application example, and is formed using a method of forming a circuit interconnection film, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the plating nucleation site, it has no effect on the film thickness of the circuit interconnection film. Also, since the conductive material is deposited by plating such as electroless plating, the possibility is substantially removed of the circuit interconnection film becoming non-uniform. Accordingly, a uniform circuit interconnection film can be formed.

It is possible to select a liquid body having low viscosity and sufficient fluidity as the catalyst for forming the conductive layer, and consequently the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a fine width in a plane direction of the interconnection base material, can be easily formed.

By performing the liquid repellent process of the side wall surface of the trench with respect to the liquid body that includes the catalyst for forming the conductive layer, the distribution of the catalyst for forming the conductive layer on the side wall surface of the trench can be suppressed.

Accordingly, by depositing a conductive material from the plating solution by the catalyst for forming the conductive layer, the circuit interconnection film is formed through lamination of the conductive material mainly from a bottom surface of the trench when the circuit interconnection film is formed, and thus the circuit interconnection film laminated from one direction and having a uniform cross section can be formed.

Accordingly, since the uniform circuit interconnection film having a narrow width in the plane direction of the interconnection base material can be easily formed, the circuit interconnection film having the film thickness that is larger than the width of the interconnection film can be easily formed.

### APPLICATION EXAMPLE 11

In the circuit interconnection film having the film thickness that is larger than the width of the interconnection film according to the above-described application example, it is preferable that the catalyst distribution process includes distributing the liquid body that includes the catalyst for forming the conductive layer on a portion having a wide width of the trench, and distributing the distributed liquid body on the portion except for the portion having wide width by capillary force.

According to this circuit interconnection film having the film thickness that is larger than the width of the interconnection film, the liquid body can be distributed even in a fine portion by using capillary force when the circuit interconnection film is formed. In the case of directly distributing the liquid body to a small trench, the liquid body can be distributed even on the fine trench, around which the liquid body is distributed due to the small size of the trench, without substantially flowing out from the trench.

### BRIEF DESCRIPTION OF THE DRAWINGS

The invention will be described with reference to the accompanying drawings, wherein like numbers reference like elements.

FIG. 1A is a plan view illustrating an outline of a circuit board.

FIG. 1B is a cross-sectional view illustrating the cross-section of connection lines provided in a circuit board.

FIG. 2 is a flowchart illustrating a circuit interconnection forming process.

FIG. 3A is an explanatory view illustrating a cross-section of a base material body before a circuit interconnection is formed.

FIG. 3B is an explanatory view illustrating a cross-section of a trench.

FIG. 3C is an explanatory view illustrating an enlarged cross-section of a trench.

FIG. 3D is an explanatory view illustrating the shape of a desmear process.

FIG. 3E is an explanatory view illustrating an enlarged cross-section of a trench after a desmear process.

FIG. 4A is an explanatory view illustrating a distribution state of a catalyst functional solution.

FIG. 4B is an explanatory view illustrating a plane shape of a trench in the neighborhood of a via forming place.

FIG. 4C is an explanatory view illustrating a state where an electroless plating solution is supplied.

FIG. 4D is an explanatory view illustrating a state where connection lines are partially formed by electroless plating.

FIG. 4E is an explanatory view illustrating a cross-section of a circuit board on which connection lines are formed.

FIG. 5A is an explanatory view illustrating a cross-section of a trench that forms the connection lines after a desmear process.

FIG. 5B is an explanatory view illustrating the relationship between an area in which the liquid repellent process has been performed and an area where a film of a catalyst for forming a conductive layer is formed.

FIG. 5C is an explanatory view illustrating a cross-sectional shape of an interconnection thin film.

FIG. 5D is an explanatory view illustrating a cross-section of a circuit board on which connection lines are formed.

FIG. 5E is an explanatory view illustrating another example of the relationship between an area in which the liquid repellent process has been performed and an area where a film of a catalyst for forming a conductive layer is formed.

FIG. 5F is an explanatory view illustrating a cross-sectional shape of an interconnection thin film.

FIG. 5G is an explanatory view illustrating a cross-section of a circuit board on which connection lines are formed.

### DESCRIPTION OF EXEMPLARY EMBODIMENTS

Hereinafter, a method of forming a circuit interconnection, a circuit board, and a circuit interconnection film having a film thickness that is larger than the width of the interconnection film will be described with reference to the accompanying drawing. In embodiments of the invention, a circuit board for packaging a semiconductor device and a process of forming a circuit interconnection on the circuit board will be described as an example. In the drawings which are referred to in the following description of the invention, for convenience of illustration, the horizontal and vertical dimensions of members or portions may differ from the actual dimensions.

### Circuit Board

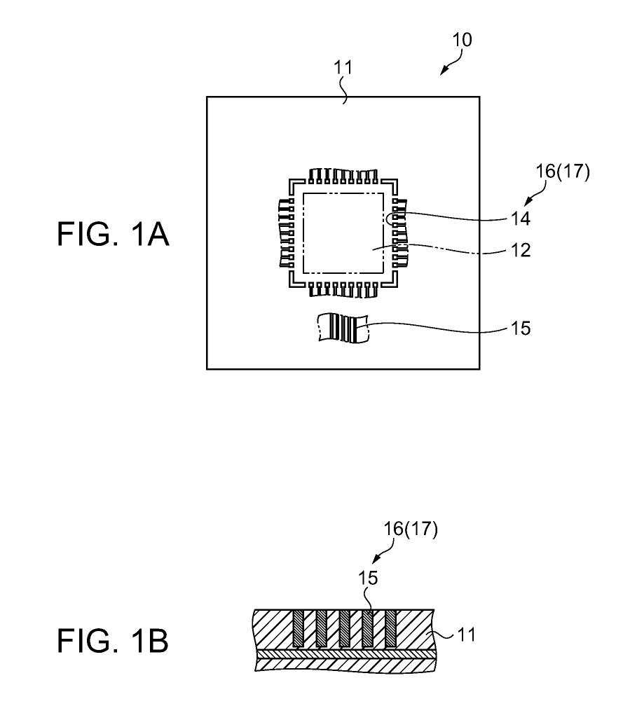

First, a circuit board 10 will be described with reference to FIGS. 1A and 1B. FIGS. 1A and 1B illustrate an outline of a circuit board. FIG. 1A is a plan view illustrating an outline of a circuit board, and FIG. 1B is a cross-sectional view illustrating the cross-section of connection lines provided in a circuit board.

The circuit board 10 is a package board on which a semiconductor device is packaged and then sealed on the board. As illustrated in FIG. 1A, a chip area 12 for installing a semiconductor chip thereon is installed substantially in the center of the circuit board 10, and a die pad 14 is formed around the chip area 12. The circuit board 10 is provided with a circuit interconnection 16 made of a good conductor such as copper. The circuit interconnection 16 is composed of terminals such as a die pad 14, connection lines 15 connecting between terminals and the like, and a circuit interconnection film 17 such as through-holes or lands of the through-holes, which are combined together.

As illustrated in FIG. 1B, the connection lines 15 correspond to a circuit interconnection film 17 having a cross-section which has a film thickness that is larger than the width of the interconnection film. The width-to-thickness aspect ratio is, for example, 5 to 10. With such a cross-sectional shape, the pitch of the connection lines 15 on the surface of a base material body 11 that is a base material of the circuit board 10 is sufficiently narrow, and the cross-sectional area of the connection lines 15 is enough for wiring conductivity.

### Process of Forming a Circuit Interconnection

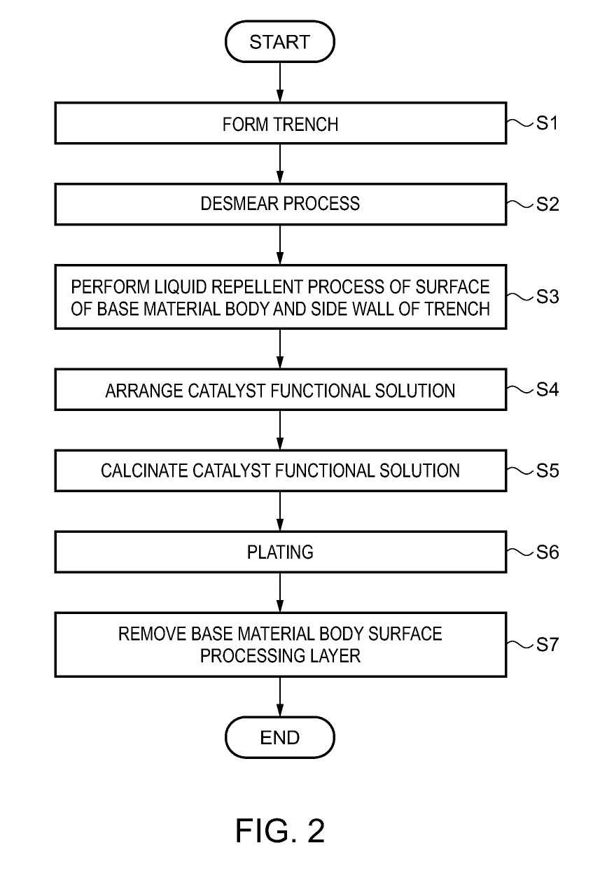

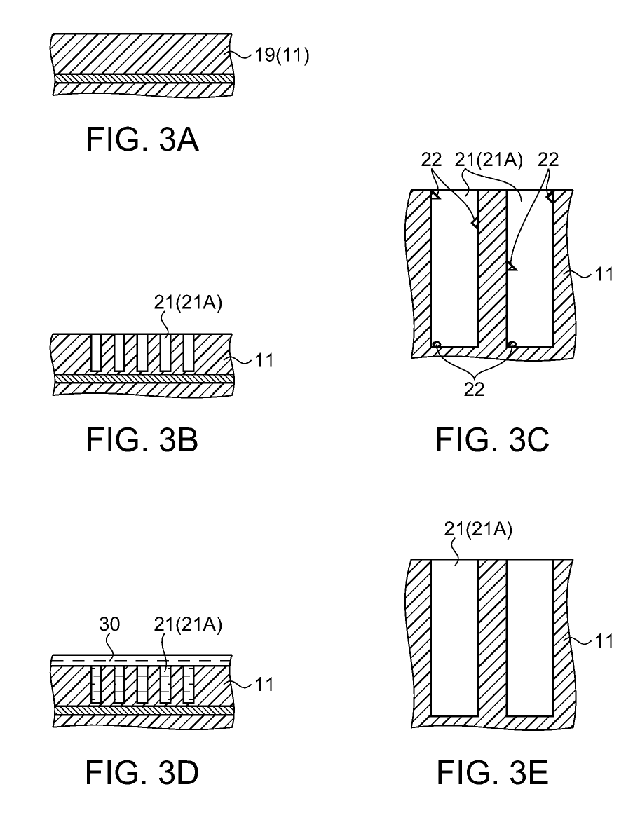

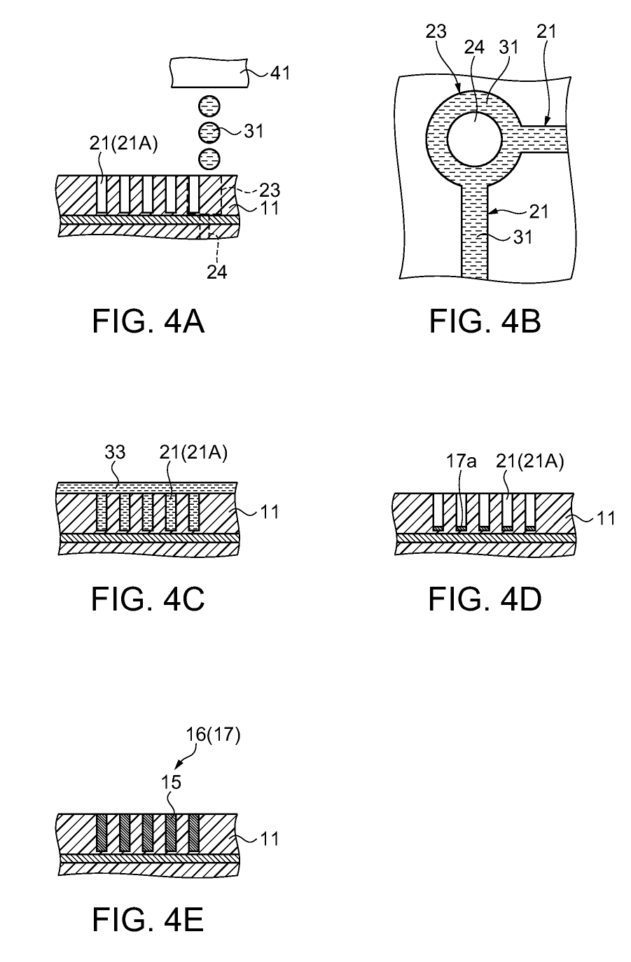

Next, a process of forming a circuit interconnection will be described with reference to FIGS. 2, 3A to 3E, and 4A to 4E. FIG. 2 is a flowchart illustrating a circuit interconnection forming process. FIGS. 3A to 3E and 4A to 4E are explanatory views illustrating the state of a circuit board in respective processes of the process of forming a circuit interconnection. FIG. 3A is an explanatory view illustrating a cross-section of a base material body before a circuit interconnection is formed, FIG. 3B is an explanatory view illustrating a cross-section of a trench, FIG. 3C is an explanatory view illustrating an enlarged cross-section of a trench, FIG. 3D is an explanatory view illustrating the shape of a desmear process, and FIG. 3E is an explanatory view illustrating an enlarged cross-section of a trench after a desmear process. FIG. 4A is an explanatory view illustrating an distribution state of a catalyst functional solution, FIG. 4B is an explanatory view illustrating a plane shape of a trench in the vicinity of a via forming place, FIG. 4C is an explanatory view illustrating a state where an electroless plating solution is supplied, FIG. 4D is an explanatory view illustrating a state where connection lines are partially formed by electroless plating, and FIG. 4E is an explanatory view illustrating a cross-section of a circuit board on which connection lines are formed.

As illustrated in FIG. 3A, the base material body 11, for example, is formed by laminating the prepreg 19. The base material body 11 is referred even with respect to a state before forming the circuit interconnection film 17 as illustrated in FIG. 3A, a state where the circuit interconnection layer 17 has been formed as illustrated in FIG. 4E, and a state while the circuit interconnection film 17 is being formed. The base material body 11 in a state before the circuit interconnection film 17 is formed corresponds to the interconnection base material.

First, in process S1 of FIG. 2, as illustrated in FIG. 3B, a trench 21A such as a trench 21 is formed. The trench 21 illustrated in FIG. 3B is a trench that is formed in a position where the connection lines 15 are formed on the circuit interconnection film 17 (circuit interconnection 16). The trench 21 is a groove having a depth-to-width ratio of, for example, equal to or larger than 5.

The trench 21A such as the trench 21 is formed by carving the prepreg 19 by laser processing. As a light source for laser processing, an excimer laser, a CO2 laser, or a YAG (yttrium/aluminum/garnet) laser may be used.

Next, in process S2 of FIG. 2, a desmear process is performed.

As illustrated in FIG. 3C, there is a possibility that a smear 22, which is formed by resin that is melted by the laser process, remains on the wall of the trench 21 (21A) or the smear 22 once separated drops and remains on the bottom of the trench 21 (21A). Since metal (in this embodiment, copper is used) that forms the circuit interconnection layer 17 is unable to be filled in a portion of the smear 22, it may cause a defect in the circuit interconnection film 17.

The desmear process includes a cleaning process, a smear removing process, a neutralization process, and a cleaning process. The smear removing process, as illustrated in FIG. 3D, is a process of dissolving the smear 22 using a desmear processing solution 30. The desmear processing solution 30 is an etching solution that can dissolve the smear. A cleaning process that is performed before the smear removing process is a process for enabling the desmear processing solution 30 to easily invade the trench 21 by cleaning the trench 21 and the like before performing the smear removing process. The neutralization process is a process of neutralizing the desmear processing solution 30, and the cleaning process that is performed after the neutralization process is a process of cleaning the neutralized desmear processing solution 30.

By performing the desmear process, as illustrated in FIG. 3E, the smear 22 of the trench 21 (21A) is removed.

Next, in step S3 of FIG. 2, the liquid repellent process of the surface of the base material body 11 and the side wall surface of the trench 21A is performed with respect to the catalyst functional solution 31 (see FIGS. 4A and 4B). More preferably, the corresponding liquid repellent process is also performed with respect to the electroless plating solution 33 (see FIG. 4C).

The liquid repellent process is performed, for example, using a CF4 plasma process using tetrafluorocarbon (tetrafluoromethane) as a process gas. The tetrafluorocarbon radical formed by the plasma acts on the surface of the base material body 11 and the resin surface of the side wall surface of the trench 21A to produce liquid repellent functional group. As is modified by the functional group, the surface of the base material body 11 and the side wall surface of the trench 21A are modified to be liquid repellent.

Although there is a high possibility that the tetrafluorocarbon radical also acts on the bottom surface of the trench 21A that connects with the side wall of the trench 21A if the side wall of the trench 21A is processed, for example, the modification of the bottom surface into the liquid repellent one is suppressed by adjusting the processing time. Since the bottom surface of the trench 21A is far apart from the plasma unit that generates plasma in comparison to the surface of the base material body 11 and the side wall of the trench 21A, it is difficult for the tetrafluorocarbon radical that is generated by the generated plasma to reach the bottom surface of the trench 21A. Accordingly, by adjusting the processing time, it can be suppressed that the bottom surface is modified into a liquid-repellent one.

It is preferable that the suppression of the modification of the bottom surface into a liquid repellent one simultaneously with the modification of the surface of the base material body 11 and the side wall surface of the trench 21A into the liquid repellent one, or an appropriate time for which the bottom surface is not modified into the liquid repellent one is obtained by experiments performed with respect to the actual circuit interconnection. At this time, it is difficult to separate a portion that is modified into a liquid repellent one and a portion that is not modified through adjustment of the processing time in a state where an accurate boundary is formed between the portions. Because of this, it is preferable that the processing time is set for which the modified portion and the non-modified portion exist inside the side wall and the most of the bottom surface is not modified.

The liquid repellent process of the surface of the base material body 11 and the side wall surface of the trench 21A with respect to the catalyst functional solution 31 in step S3 corresponds to the liquid repellent process.

Next, in process S4 of FIG. 2, the catalyst functional solution 31 is distributed on the trench 21A. The process of distributing the catalyst functional solution 31 on the trench 21A includes a catalyst droplet distribution process and a catalyst liquid invading process.

The catalyst droplet distribution process is performed by landing droplets on a portion having a wide width in the trench 21A using an ink jet type droplet discharge device. The ink jet type droplet discharge device can precisely land droplets on an arbitrary position of a work by relatively moving a discharge head 41 having a discharge nozzle for discharging the droplets and a work on which the droplets are to be landed and positioning a droplet distribution unit of the work in a position that is opposite to the discharge nozzle with good accuracy. It is possible to make the size of the droplets constant with good accuracy. By using the ink jet type droplet discharge device, a desired amount of catalyst solution can be distributed on a desired portion of the trench 21A. In the process of distributing the catalyst droplets, as illustrated in FIG. 4A, in order to form a land that is connected to an end of the via hole, the catalyst functional solution 31 is distributed by discharging the droplets of the catalyst functional solution 31 toward a land trench 23 and the like formed on an open end portion of a hole 24 below the via hole. The land trench 23 corresponds to a portion having a wide width in the trench 21A.

In the trench 21A, the catalyst functional solution 31 is widely spreaded on a portion having a width that is smaller than the droplet diameter of the catalyst functional solution 31, such as the trench 21, by the catalyst solution filling process. As illustrated in FIG. 4B, for example, the catalyst functional solution 31 distributed on the portion having a wide width such as the land trench 23 is filled into and invades the portion having a narrow width such as the trench 21 by a capillary force. It is preferable that the liquid having a low viscosity is selected as the catalyst functional solution 31 so as to facilitate the suction by the capillary force. A package substrate of most semiconductor devices has an outer dimension of about 3 cm even if it is large. In the trench 21 on the corresponding package substrate, it is confirmed that the invading distance of about 3 cm can be sufficiently realized. The catalyst functional solution 31 is a liquid body including palladium ions, and copper plating is grown, starting from the nucleation site of the metal palladium deposited from the catalyst functional solution 31. Because of this, it is sufficient if the catalyst functional solution 31 is distributed to the extent that it is possible to insert the nucleation sites of the palladium in some places at a density sufficient to form the deposition metal film, but it is not necessary for the catalyst functional solution 31 to have the function as a conductive layer. In the respective portions of the trench 21A, it is sufficient if the catalyst functional solution 31 is distributed to the extent that there is no problem regarding the deposition rate, but it is unnecessary to distribute the catalyst functional solution 31 uniformly.

Next, in process S5 of FIG. 2, the catalyst functional solution 31 is calcinated. The calcinating, for example, is performed for 30 minutes to one hour at a calcinating temperature of about 70° C. to 250° C. to remove the solvent of the functional solution. By calcinating the catalyst functional solution 31, the palladium ions included in the catalyst functional solution 31 becomes metal palladium to form a layer of catalyst for forming the conductive layer on the bottom surface of the trench 21A. The catalyst functional solution 31 corresponds to the liquid body that includes the catalyst for forming the conductive layer.

Next, in process S6, by performing a plating process, a circuit interconnection film 17 is formed. The plating process includes an electroless plating process and an electro plating process.

In the electroless plating process, as illustrated in FIG. 4C, an electroless plating solution 33 is distributed in an area that includes the trench 21A on which the catalyst film is formed. Metal copper is deposited from copper ions of the electroless plating solution 33 by the catalyst, and a redox-type neutral PH electroless plating solution, which uses metal such as copper as the reducing agent, can be used. Since the corresponding plating solution has a high deposition rate and cause no damage to the base material (base material body 11) or the catalyst layer for forming the conductive layer, it is preferable as the electroless plating solution. Also, it is possible to use a general alkaline plating solution.

In the electro plating process, the circuit interconnection film 17 is formed by laminating metal copper on the interconnection thin film 17a using the interconnection thin film 17a as the conductive layer.

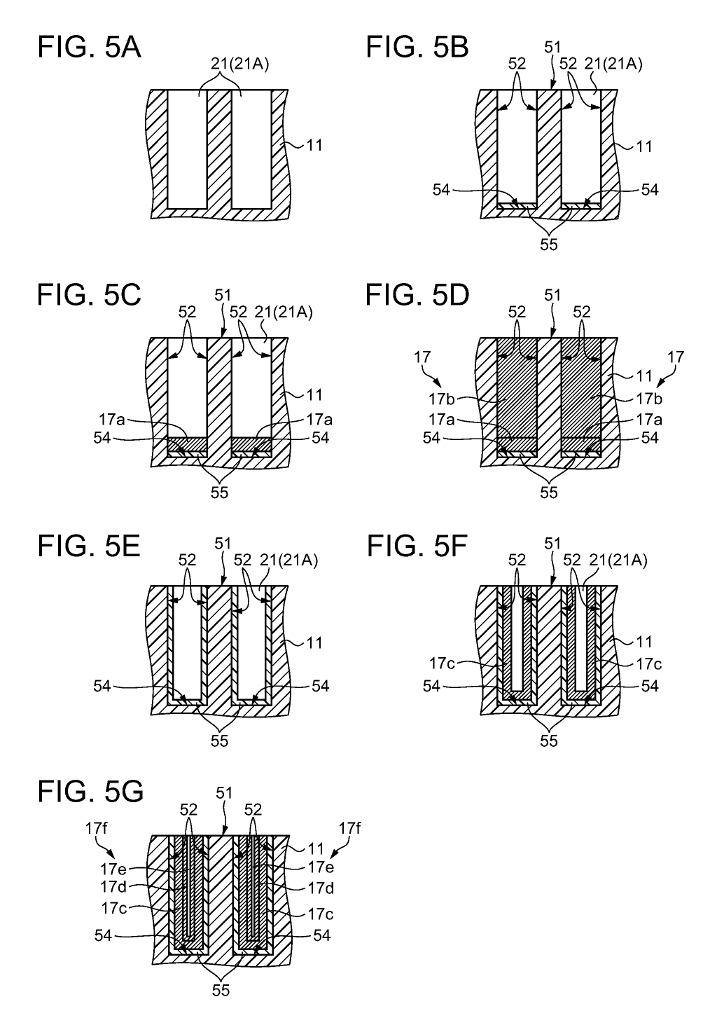

Here, the relationship between an area in which the liquid repellent process has been performed and a cross-sectional shape of the circuit interconnection film 17 will be described with reference to FIGS. 5A to 5G. FIGS. 5A to 5G are explanatory views illustrating cross-sectional shapes of portions of the connection lines of the circuit board in the process of forming the circuit interconnection film by laminating copper. FIG. 5A is an explanatory view illustrating a cross-section of a trench that forms the connection lines after a desmear process, and FIG. 5B is an explanatory view illustrating the relationship between an area in which the liquid repellent process has been performed and an area where a film of a catalyst for forming a conductive layer is formed. FIG. 5C is an explanatory view illustrating a cross-sectional shape of an interconnection thin film, FIG. 5D is an explanatory view illustrating a cross-section of a circuit board on which connection lines are formed, and FIG. 5E is an explanatory view illustrating another example of the relationship between an area in which the liquid repellent process has been performed and an area where a film of a catalyst for forming a conductive layer is formed. FIG. 5F is an explanatory view illustrating a cross-sectional shape of an interconnection thin film, and FIG. 5G is an explanatory view illustrating a cross-section of a circuit board on which connection lines are formed.

The trench 21 (21A) shown in FIG. 5A is the trench 21 that is the same as the trench 21 (21A) from which the smear 22 has been removed as illustrated in FIG. 3E.

First, as described above, a case where the liquid repellent process of the surface 51 of the base material body 11 and the side wall surface 52 of the trench 21A (trench 21) has been performed with respect to the catalyst functional solution 31 will be described.

As illustrated in FIG. 5B, in the case where the liquid repellent process of the surface 51 and the side wall surface 52 has been performed with respect to the catalyst functional solution 31, a catalyst layer 55 for forming a conductive layer is formed only on the bottom surface 54 of the trench 21.

Next, by performing the electroless plating process, as illustrated in FIG. 5C, the interconnection thin film 17a is formed to be laminated on the catalyst layer 55 for forming the conductive layer. Since the catalyst layer 55 for forming the conductive layer is formed only on the bottom surface 54, the interconnection thin film 17a is formed on the bottom surface 54 of the trench 21.

Next, by performing the electro plating process, as illustrated in FIG. 5D, the interconnection film body 17b is formed to be laminated on the interconnection thin film 17a. Since the interconnection thin film 17a is formed in a plane shape on the bottom surface 54 of the trench 21, the plane surface of the interconnection film body 17b is laminated and becomes thick to form a substantially rectangle-shaped cross-section. By the interconnection thin film 17a and the interconnection film body 17b, the circuit interconnection film 17 having a substantially rectangle-shaped cross-section is formed.

Next, a case where the liquid repellent process of the surface 51 of the base material body 11 only has been performed with respect to the catalyst functional solution 31 will be described.

As illustrated in FIG. 5E, in the case where the liquid repellent process of the surface 51 only has been performed with respect to the catalyst functional solution 31, the catalyst functional solution 31 is also attached to the side wall surface 52 of the trench 21A in addition to the bottom surface 54 of the trench 21A, and thus a catalyst layer 55 for forming a conductive layer is formed on the bottom surface 54 and the side wall surface 52.

Next, by performing the electroless plating process, as illustrated in FIG. 5F, the interconnection thin film 17c is formed to be laminated on the catalyst layer 55 for forming the conductive layer. Since the catalyst layer 55 for forming the conductive layer is formed only on the bottom surface 54 and the side wall surface 52, the interconnection thin film 17c is formed on the bottom surface 54 and the side wall surface of the trench 21 to form a substantially “U”-shaped cross-section.

Next, by performing the electro plating process, as illustrated in FIG. 5G, the interconnection film body 17d is formed to be laminated on the interconnection thin film 17c. Since the interconnection thin film 17c is formed in a substantially “U”-shaped cross-section on the bottom surface and the side wall surface 52 of the trench 21, the interconnection film body 17d is formed to fill in the space inside the substantially “U”-shape in three directions. As the interconnection thin film 17d is formed, the space inside the substantially “U”-shape becomes narrower, and thus it becomes difficult for the plate solution to be supplied into the space. Accordingly, there is a high possibility that the space inside the substantially “U”-shape is not filled as a whole, but a gap 17e remains. As the gap 17e remains, there is a high possibility that the formed circuit interconnection film 17f becomes a film that includes the gap 17e inside the substantially rectangular cross-section. Since the circuit interconnection film 17f includes the gap 17e inside the substantially rectangular cross-section, there is a high possibility that the conductivity is degraded in comparison to the circuit interconnection film 17 having a substantially rectangle-shaped cross-section as a whole.

Next, in process S7 of FIG. 2, a surface processing layer (liquid repellent layer) on the surface of the base material body 11 formed in process S3 is removed. The removal of the surface processing layer is to prevent the influence of the existence of the surface processing layer when the base material body 11 on which the circuit interconnection 16 is formed is further processed. Of course, if there is no influence during the further processing or if it is not necessary to further process the base material body 11, the surface processing layer may not be removed.

By performing process S7, the circuit interconnection film 17 is formed on the base material body 11 to terminate the circuit interconnection forming process for forming the circuit interconnection 16.

Hereinafter, effects according to the embodiments of the invention will be described. In this embodiment, the following effects can be obtained.

(1) The connection lines 15 correspond to the circuit interconnection film 17 that has a large cross-section having a thickness that is larger than the width thereof. Accordingly, since the reduction of the cross-sectional area of the connection lines 15 according to the reduction of the line width of the connection lines 15 can be suppressed, the deterioration of the conductive capability of the connection lines 15 caused by reducing the line width of the connection lines 15 is suppressed, and thus the line width and the distribution pitch of the connection lines 15 can be shortened.

(2) The surface of the base material body 11 is processed by a liquid repellent process with respect to the catalyst functional solution 31. Accordingly, the catalyst functional solution 31 can be prevented from attaching to the surface of the base material body 11. If the catalyst functional solution 31 is attached to the surface of the base material body 11, a conductive film is also formed on the surface of the base material body 11, and there is a possibility that the neighboring connection lines 15 maybe short-circuited by the corresponding conductive film. By performing a liquid repellent process with respect to the surface of the base material body 11, the possibility of such a short circuit can be decreased.

(3) The liquid repellent process of the side wall surface 52 of the trench 21A (trench 21) has been performed with respect to the catalyst functional solution 31, and thus the circuit interconnection film 17 having a substantially uniform rectangle-shaped cross-section as a whole can be formed. Like the case where the liquid repellent process of the side wall surface 52 has not been performed with respect to the catalyst functional solution 31, the circuit interconnection film includes the gap 17e, and thus the deterioration of the conductivity can be suppressed.

(4) The trench 21A is formed by carving the prepreg 19 by a laser process. Using the laser process, the trench 21A can be promptly formed in an accurate shape. A trench having a depth that is larger than the width thereof, such as the trench 21, can be easily formed.

(5) In the process of distributing catalyst droplets, the catalyst functional solution 31 is distributed by discharging the droplets of the catalyst functional solution 31 to the land trench 23 and the like. By determining the portion having a wider width than that of other portions of the trench 21A, such as the land trench 23, as the landing position of the droplets of the catalyst functional solution 31, the droplets of the catalyst functional solution 31 are prevented from landing on a portion that is separated from the trench 21A.

(6) With respect to the portion having a width that is narrower than the diameter of the droplets of the catalyst functional solution 31 such as the trench 21, the catalyst functional solution 31 distributed on a portion having a wide width such as the land trench 23 flows into the portion having a narrow width such as the trench 21 by a capillary force, and by this catalyst solution flow process, the catalyst functional solution 31 is widely spreaded. Accordingly, the catalyst functional solution 31 can be distributed in a fine portion such as the trench 21. Also, when the catalyst functional solution 31 is distributed, the catalyst functional solution 31 is prevented from being attached to a portion that is separated from the trench 21A.

(7) The plating process has an electroless plating process and an electro plating process. By forming the electro plating process, the circuit interconnection film 17 can be formed in a short time in comparison to the electroless plating process.

Although preferred embodiments of the invention have been described with reference to the accompanying drawing, the preferred embodiment is not limited thereto. Diverse modifications can be made within the range that does not depart from the spirit of the invention, and embodiments can be performed as follows.

### MODIFIED EXAMPLE 1

In the above-described embodiment, the plating process of the circuit interconnection forming process includes the electroless plating process and the electro plating process, but it is not essential to perform the electro plating process together with the electroless plating process. The circuit interconnection forming method may be a method of forming the circuit interconnection film only by the electroless plating process.

### MODIFIED EXAMPLE 2

In the above-described embodiment, the catalyst functional solution 31 is distributed on the trench 21A using the ink jet type droplet discharge apparatus, but it is not essential to use the ink jet type droplet discharge apparatus to distribute the functional solution that includes the catalyst for forming the conductive layer. Any droplet discharge apparatus that is different from the ink jet type droplet discharge apparatus may be used, and the functional solution may be distributed using another apparatus that is different from the droplet discharge apparatus.

### MODIFIED EXAMPLE 3

In the above-described embodiment, in the process of forming the circuit interconnection, a desmear process including a cleaning process, a smear removing process, a neutralization process, and a cleaning process is performed. However, performing of the desmear process is not essential. If it is possible to suppress the occurrence of smear when the trench is formed, the process of forming the circuit interconnection may be a process that does not include the desmear process.

### MODIFIED EXAMPLE 4

In the above-described embodiment, in the process of forming the circuit interconnection, a desmear process including a cleaning process, a smear removing process, a neutralization process, and a cleaning process is performed.

In the smear removing process, as the smear 22 is dissolved by the desmear processing solution 30, the wall surface of the trench 21A is also dissolved. The dissolving of the wall surface of the trench 21A may mean that the shape of the trench 21A is damaged or the wall surface of the trench 21A is finely dissolved to form a fine hole. Under the assumption that the shape of the trench 21A is damaged, it is preferable that the smear removing process in the desmear process is not performed. Under the assumption that the fine hole is formed on the wall surface of the trench 21A, the fine hole on the wall surface of the trench 21A accelerates the suction of the catalyst functional solution 31, and improves the adhesion of the copper deposited from the electroless plating solution 33. Accordingly, it is preferable to perform the smear removing process. It is preferable to determine whether to perform the smear removing process, or performance conditions in consideration of the above-described conditions.

### MODIFIED EXAMPLE 5

In the above-described embodiment, the liquid repellent process is performed using a CF4 plasma process. However, it is not essential that the processing method that is used to perform the liquid repellent process with respect to the base material surface is the CF4 plasma process. The forming of the liquid repellent film may be performed by spreading a modification solution for modifying the material to have a liquid repellent property or by extracting the liquid repellent film through spreading of the liquid body that includes the material of the liquid repellent film. Also, the liquid repellent film may be formed by spreading a liquid repellent functional solution on a sheet such as a film and transferring the liquid repellent functional solution on the sheet to the base material surface through lamination of the corresponding film on the base material.

The entire disclosure of Japanese Patent Application No. 2010-013924, filed Jan. 26, 2010 is expressly incorporated by reference herein.

What is claimed is:

1. A method of forming a circuit interconnection on a circuit board comprising:
forming a trench that corresponds to a shape of the circuit interconnection on an interconnection base material that forms the circuit interconnection;
performing a liquid repellent process of at least the base material surface of the interconnection base material and a side wall surface of the trench with respect to a liquid body that includes a catalyst for forming a conductive layer;
distributing the liquid body that includes the catalyst for forming a conductive layer on the trench; and
forming a conductive circuit interconnection film that forms the circuit interconnection by distributing a plating solution in a range that includes the trench and depositing a conductive material from the plating solution through the catalyst for forming the conductive layer.

2. The method according to claim 1, wherein the trench is formed by a laser process in the forming of the trench.

3. The method according to claim 1, further comprising a desmear processing process.

4. The method according to claim 1, wherein the distributing of the catalyst comprises landing and distributing the liquid body that includes the catalyst for forming the conductive layer on a portion of the trench using an ink jet type discharge device.

5. The method according to claim 1, wherein the distributing of the catalyst comprises distributing the liquid body that includes the catalyst for forming the conductive layer on a portion having a wide width of the trench, and distributing the liquid body on the portion except for the portion having wide width by capillary force.

6. The method according to claim 1, wherein the forming of the film comprises forming the circuit interconnection film by electroless plating.

7. The method according to claim 1, wherein the forming of the film comprises forming the circuit interconnection film by electroless plating and forming the circuit interconnection film by electro plating.

8. A circuit board comprising:
a circuit interconnection that is formed using a method of forming a circuit interconnection which includes
forming a trench that corresponds to a shape of the circuit interconnection on an interconnection base material that forms the circuit interconnection;
performing a liquid repellent process of at least the base material surface of the interconnection base material and a side wall surface of the trench with respect to a liquid body that includes a catalyst for forming a conductive layer;
distributing the liquid body that includes the catalyst for forming a conductive layer on the trench; and
forming a conductive circuit interconnection film that forms the circuit interconnection by distributing a plating solution in a range that includes the trench and depositing a conductive material from the plating solution through the catalyst for forming the conductive layer.

9. The circuit board according to claim 8, wherein the distributing of the catalyst comprises distributing the liquid body that includes the catalyst for forming the conductive layer on a portion having a wide width of the trench, and distributing the distributed liquid body on a portion except for the portion having wide width by capillary force.

10. A circuit interconnection film, which has a film thickness that is larger than a width of the interconnection film, and is formed using a method of forming a circuit interconnection film that comprises forming a trench that corresponds to a shape of the circuit interconnection film on an interconnection base material that forms the circuit interconnection film; performing a liquid repellent process of at least the base material surface of the interconnection base material and a side wall surface of the trench with respect to a liquid body that includes a catalyst for forming a conductive layer; distributing the liquid body that includes the catalyst for forming a conductive layer on the trench; and
forming a conductive circuit interconnection film by distributing a plating solution in a range that includes the trench and depositing a conductive material from the plating solution through the catalyst for forming the conductive layer.

11. The circuit interconnection film having a film thickness that is larger than a width of the interconnection film according to claim 10, wherein the distributing of the catalyst comprises distributing the liquid body that includes the catalyst for forming the conductive layer on a portion having a wide width of the trench, and distributing the distributed liquid body on the portion except for the portion having wide width by capillary force.
